(19) United States
(12) Patent Application Publication
(10) Pub. No.: US 2010/0140778 A1
(43) Pub. Date: Jun. 10, 2010

(54) PACKAGE, METHOD OF MANUFACTURING THE SAME AND USE THEREOF

(75) Inventors: Johannes Wilhelmus Weekamp, Eindhoven (NL); Nicolaas Johannes Anthonius Van Keen, Eindhoven (NL)

Correspondence Address: PHILIPS INTELLECTUAL PROPERTY & STANDARDS, PO BOX 3001, BRIARCLIFF MANOR, NY, 10510-8001, US

(73) Assignee: KONINKLIJKE PHILIPS ELECTRONICS N.V., EINDHOVEN (NL)

(21) Appl. No.: 11/993,739

(22) PCT Filed: Jul. 4, 2006
(86) PCT No.: PCT/IB06/52243

§ 371 Date: Dec. 21, 2007

(30) Foreign Application Priority Data
Jul. 7, 2005 (EP) 05106169.5
Jul. 4, 2006 (IB) PCT/IB2006/052243

(51) Int. Cl. H01L 23/48; H01L 21/56

(52) U.S. Cl. 257/690; 438/124; 257/E23.01; 257/E21.502

(57) ABSTRACT

The flexible package (100) comprises coupling means (20) for electrical coupling to an external component, a chip (30) with contact pads (32) that face the coupling means (20) and are electrically coupled thereto, and an electrically insulating encapsulation (40) encapsulating the chip (30) and being attached to the coupling means (20), said encapsulation (40) and said coupling means (20) constituting a substrate for the chip (30). The package (100) further comprises means (50) for handling the package (100). This means (50) is mechanically connected to the coupling means (20) through the encapsulation (40) only. The package (100) is suitable for assembly to a foil, which may be attached to or integrated in an article such as a security paper.

The invention relates to a package comprising means for external coupling, a chip, contact pads of which chip are electrically coupled to said means for external coupling and an encapsulation encapsulating the chip and said means for external coupling.

The invention also relates to a method of manufacturing thereof.

The invention further relates to a foil with such a package and to an article, particularly a security paper, comprising such a foil with package.

Such a package and such an article are for instance known from DE19630648 A1. The known article is a banknote. The means for external coupling are herein an antenna. The foil is herein a foil with metallic patterns or a metallic foil, which is conventionally integrated in the banknote for security purposes. The assembly to this foil is preferred as it allows a proper integration into the paper mass during the manufacture of the banknote. Additionally, the use of the metallic foil is preferred in that it is relatively rigid and protects the chip against cracking. The encapsulation is herein a mass that is tough and impact-resistant. It is observed that other possibilities for the antenna are mentioned as well; the antenna could be provided on the chip or the metallic foil could be used as the antenna in itself.

It is a disadvantage of the known package that integration into the banknote is relatively difficult. The encapsulation is conventionally an epoxy, which after curing is rigid and quite inert. A proper adhesion to the metallic foil is then not easy. The alternative of providing the encapsulation only after the assembly of the chip to the foil does not appear effective either, as the epoxy is generally provided in a transfer moulding process that cannot be carried out with such a foil effectively; i.e. the size of the encapsulation is relatively small in comparison with the size of the foil. Moreover, the moulding process requires a temperature in the order of 150-200° C. or more, and it is not clear that the foil withstands a treatment at such a temperature.

It is therefore a first object of the invention to provide a package, which can be assembled to such a foil in an improved, more adequate manner.

It is a second object of the invention to provide a method of manufacturing such a package.

The first object is achieved in a flexible package, which comprises coupling means for electrical coupling to an external component, and comprises a chip with contact pads that face the coupling means and are electrically coupled thereto, and comprises an electrically insulating encapsulation encapsulating the chip and being attached to the coupling means, said encapsulation and said coupling means constituting a substrate for the chip, and which flexible package further comprises means for handling that is mechanically connected to the means for external coupling through the encapsulation only.

The second object is achieved in that the method comprises the steps of:

providing a carrier with a carrier layer and a pattern of electrically conductive tracks defining coupling means;

assembling the chip to the carrier, wherein contact pads of the chip are electrically coupled to the coupling means of the carrier;

providing an encapsulation encapsulating the chip and extending on at least one surface of the carrier, and

removing the carrier layer partially, such that the coupling means can be used for electrically coupling the package to an external component and such that means for handling the package are preserved, which means is mechanically attached to said conductive tracks only through the encapsulation.

According to the invention, the package is flexible and the assembly is enabled in that the package is provided with handling means. Particularly, according to the method, the carrier comprises a carrier layer that is partially removed during the packaging, while portions thereof function as handling means.

The flexibility allows the package to be assembled as a process of laminating flexible foils, which process is easier than the provision of a rigid part on a foil. The package of the invention may be regarded as a continuous or semi-continuous foil. As the carrier layer is removed after forming of the encapsulation, the body of the package is formed by the encapsulation. This encapsulation is not rigid and generally comprises an organic material, and therewith foil alike. Contrarily, the package of the prior art is merely a tiny discrete component. That small size is needed in the prior art, as a large-size rigid prior art package would be a disadvantageous in the otherwise flexible banknote.

It is observed that the package of the invention may even be a foil in that the individual packages are not separated from each other. In one embodiment, it is possible that the assembly of the package and the foil is even carried out as a reel-to-reel process based on two continuous foils of the same format.

An apparent disadvantage would be that alignment is more difficult with flexible packages. However, such a high resolution is generally not required when assembled a package with a foil. Moreover, the handling means allow handling and also positioning of the package on the foil. Without such handling means, the integrated circuit or the encapsulation is used as the handling means. However, the encapsulation is a flexible body, if it is at all a body, with at the inside a chip. Applying forces herein may lead to delamination of the encapsulation from chip or coupling means, or may lead to unexpected forces on the chip. If otherwise it is easier to use the chip as handling means, then the force applied to the chip will also be exerted on the connection between the coupling means and the chip. This may be a glue layer, but generally comprises solder balls, which are inherently vulnerable due to their small size.

It is moreover observed that handling means are known in the leadframe world, as actually the frame-part of the leadframe. However, this frame is not part of any individual package.

It is also observed that a method of manufacturing a package in which a carrier layer is completely or partially removed, is known per se, such as from JP-A 59-208756. However, there is no suggestion therein that the package is flexible or that it is provided with handling means. For reasons of clarity it is observed that the term ‘flexibility’ is understood, in the context of this application, as allowing the bending of the package without the need to exert substantial stress.

Encapsulations that allow flexibility are known per se, a suitable material is for instance polyimide. In one embodiment, the encapsulation is merely a sealing layer. This provides an excellent flexibility as a result of the thickness reduction. Additionally, the sealing layer may be cut after the assembly of the package so as to remove the handling means. Moreover, such a sealing layer does not add any additional height to the package.

A preferred material for the sealing layer is parylene. Parylene is the generic name of a unique family of thermoplastic polymers that are deposited by using the dimer of para-xylylene (di-para-xylelene or DPXN). Parylene can be deposited under vacuum conditions from a vapour phase at room temperature. There are three types of commercially available parylene, but many more can be envisaged. The basic member is poly-para-xylylene (also referred to as Parylene N), a linear and highly crystalline polymer which exhibits a low dissipation and a high dielectric strength. A second type, Parylene C, has para-xylylene monomers which have a chlorine atom replacing one of the aromatic hydrogen atoms in Parylene N. Parylene also has a low permeability to moisture and other corrosive gases. Parylene D, the third member of the series, also has para-xylylene monomers, but with two chlorine atoms replacing two aromatic hydrogen atoms in the monomer of Parylene N. Parylene D has similar properties to Parylene C, with the ability to withstand higher temperatures.

The coupling means comprise preferably an antenna for wireless transmission of energy and data. Such an antenna can be a dipole antenna or an inductor, as known per se. The external component is then in particular a reader. Alternatively or additionally, the coupling means may comprise contact pads for galvanic contact with an external component. That is in generally any kind of circuit board or socket.

Preferably, the handling means are present on at least two opposite sides of the package, i.e. in a cross-sectional view left and right of the chip. The handling means may be implemented as bars, but alternatively as cubic blocks. In the latter case, it appears suitable to apply more than blocks. One may for instance provide a block in each corner of the package. If desired one may of course use different shapes for the handling means, such as stars, crosses, triangles, L-shapes, T-shapes etcetera.

The size of the handling means depends on the handling equipment in use. Generally, the shortest dimension of a block is for instance about 10 microns, but the shortest dimensions in a lateral direction may also be 100 microns or even more. Particularly in combination with the method of the invention, the thickness depends on the thickness of the carrier layer. This thickness is suitably in the order of 30 to 100 microns, when using a metal foil. When using a polymer foil it may be larger. However, metal is preferred as it has a relatively big mass and in that it is rigid. Therefore, it is very suitable to serve as carrier layer and also to serve as the handling means. Moreover, the metal of the handling means principally allows to use advanced tools for the handling, such as vacuum, electromagnetic forces and the like.

In a further embodiment of the invention, the handling means are defined to be present on opposite sides of a foil to which the package need to be attached. Herein, the handling means are effective positioning means. With opposite sides, here is referred to the side faces in particular. Thus, the handling means are after assembly present left and right of the foil. Alternatively, the foil may be provided with cavities or through-holes in which the handling means fit.

After assembly with the foil, the handling means may be removed. However, this is not absolutely necessary, and may even be unhandy in the case that the handling means are present in cavities or through-holes. In the case that a plurality of packages is attached to one foil, such that the handling means are left and right, these may be removed in a single dicing operation.

The embodiment in which the handling means are defined to be located left and right of a foil, is particularly preferred in combination therewith that the coupling means are defined only on top of the carrier layer. When using a metal carrier layer, there are basically two different embodiments of a package manufacturing with removable carrier layer. In one embodiment, such as known from JP-A 59-208756, the pattern of conducting tracks—and thus the coupling means—are merely present on top of the carrier layer. The complete carrier layer is then removed, with the exception of the handling means. In that case, the handling means protrude from the encapsulation beyond the coupling means. If the handling means are located adjacent to the foil, the package lies basically flat on the foil.

In an alternative embodiment, such as known from U.S. Pat. No. 6,451,627, the carrier layer is removed only partially. It is effectively patterned to constitute portions of the coupling means. In this embodiment, the handling means will not protrude beyond the coupling means. However, with a sufficient lateral distance between the coupling means and the handling means, the encapsulation may be bent to lie flat on the foil. This embodiment is however not preferred, as the total thickness of the package will increase.

In a further embodiment, the encapsulation extends in apertures between the coupling means such that it is exposed at a side of the coupling means facing away from the chip. This extension has as a first advantage that a proper attachment of the coupling means to the encapsulation is achieved. A second advantage is that this provides an additional site for attachment between the foil and the encapsulation. Generally, attachment of organic materials to each other is better than that between metal and a foil of organic material. An additional attachment site between larger areas with a less intensive attachment is thus beneficial for the overall attachment.

It is observed that the chip is suitably thinned back to reduce the overall thickness and increase the flexibility. One example of a very thin chip is known from WO-A 2005/29578. This chip may be provided with a resin layer both on its front side and on its back side after thinning and partial removal of the substrate. Such a chip may be effectively used in combination with the sealing layer embodiment of the invention. The chip is already provided with protective layers, and thus a complete encapsulation were superfluous and leading to an undesired increase in thickness only. Although the chip is suitably made on the basis of a semiconductor substrate, e.g. of silicon, it is not excluded that it is defined on the basis of an organic semiconductor material.

The invention further relates to the assembly of the package with the foil, to the resulting assembly of package and foil, and to an article in which such a foil with package is integrated. The advantage for the article is that the resulting package may be really thin and be properly attached to the handling foil. The foil can therefore be rolled up as if no package were attached to it.

If the article is a security paper, such as a banknote, a passport, a check or ticket, the foil is suitably a security thread, as known per se to the skilled person in the field of security paper. Alternatively, the foil may be a carrying foil for optically active elements. A security thread is preferably patterned so that the coupling means are electrically isolated from the metal of the thread. Alternatively or additionally, a layer of electrically insulating material may be applied to cover the exposed coupling means. Such layer can for instance be applied after removal of the carrier layer. The layer of electrically insulating material could be a foil. This foil would then be integrated with the security thread only afterwards.

For labeling applications, it may be more preferred to use a flexible encapsulation instead of merely a sealing layer. The package may then be assembled to the foil with the encapsulation, such that the coupling means will face away from the foil. This may result in a package that is slightly thicker, but in which the chip is embedded in the encapsulation.

These and other aspects will be further explained with reference to the Figures, in which:

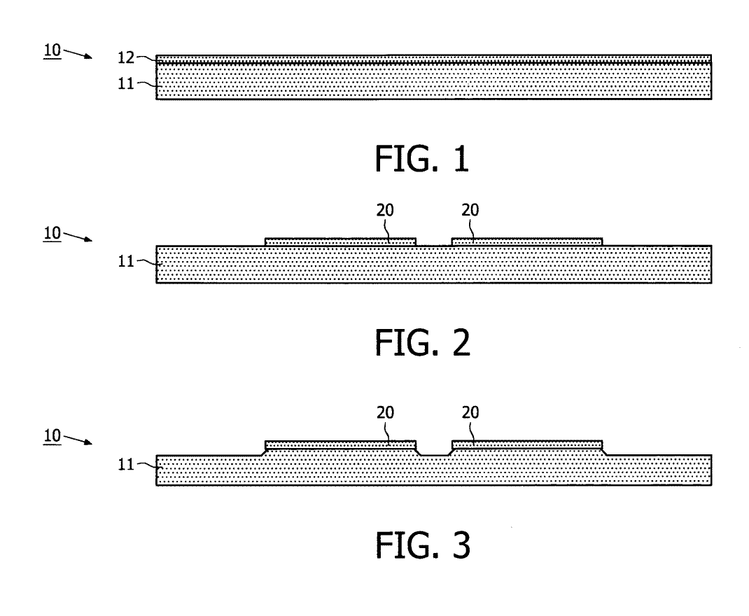

FIGS. 1-6 show in cross-sectional view several stages in the manufacture of the package of the invention.

The Figures are purely diagrammatical and not drawn to scale. Equal reference numerals in different Figures refer to the same or corresponding parts. The figures are meant for illustrative purposes and alternatives will be clear to the skilled person on the basis of the description.

FIG. 1 shows a carrier 10 having a carrier layer 11 and a top layer 12. The carrier layer 11 comprises in this case aluminum and has a thickness of about 30 microns. The top layer 12 comprises copper in a thickness of about 1-20 microns, and in this example of about 2 microns.

FIG. 2 shows the carrier 10 after patterning of the top layer 12 to create coupling means 20. The coupling means constitute for instance an antenna. In this example, these will also be exposed and be useful as contact pads for galvanic coupling. For the patterning of the top layer 12 use may be made of a mask of a material that constitutes a solderable interface, such as NiAu, NiPd, NiAuPd, Au and the like.

FIG. 3 shows the carrier after an additional step in which an etching treatment is carried out in the carrier layer 11. This results in some underetch under the coupling means 20, and any other patterns defined in the top layer 12. Although the example shows a carrier 10 on the basis of Al—Cu, in which the patterns in the top layer 12 are defined by etching, it is well known that there are several alternatives. Both the top layer 12 and the carrier layer 11 could be defined in Cu, if an intermediate barrier layer is present, for instance of Ni, Mb, Ti or even Al. The carrier layer 10 could also be of a suitable non-metallic material, provided that it survives the temperature and conditions used during bonding and encapsulation. These conditions need not to be strict. The coupling means 20 and any other conductive patterns in the top layer 12 could be provided in an electroplating process instead of an etching process. Additionally, the carrier 10 may be provided with a separate mask on its bottom side, for instance of a suitable metal, such that the carrier layer 11 may be patterned without the need for an additional photolithographical step after the assembly of a chip. Effectively, the carrier layer 10 could have been patterned already to define grooves around the handling means. This allows that the carrier layer 10 may be removed in a peeling process, instead of an etching process.

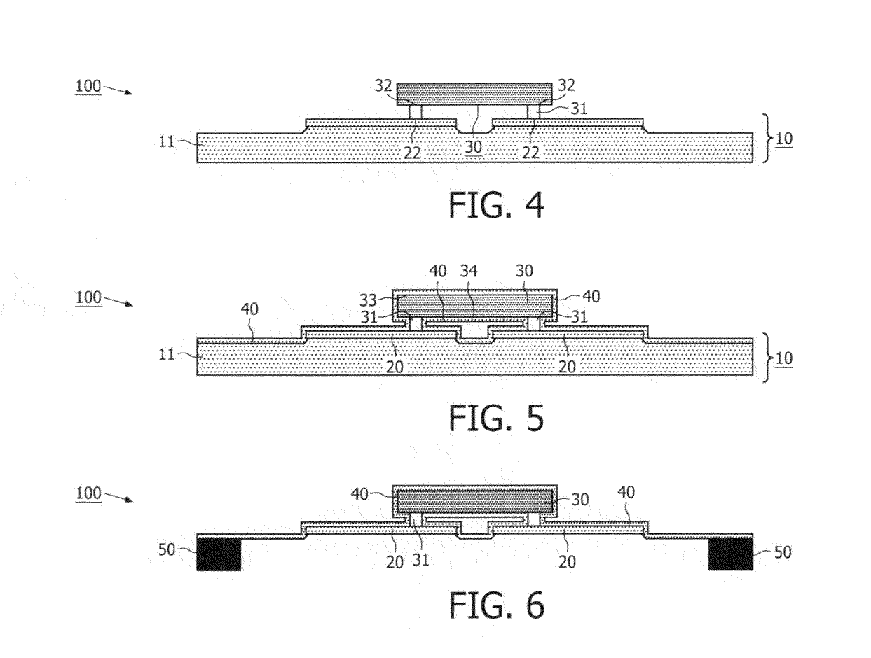

FIG. 4 shows the package 100 in a stage after assembly of the chip 30 to the carrier 10. In this example the chip 30 is assembled to the carrier 10 in a flip-chip orientation with solder balls 31 extending between the contact pads 32 of the chip 30 and the contact pads 22 defined as part of the coupling means 20 or connected thereto. However, use could be made of anisotropically conductive glue. A further option is given in the use of a dielectric glue. The electrical coupling between the coupling means 20 and the chip 30 is then established with capacitive coupling. Although not shown here, use could be made of an underfilling material to fill the gap between the chip 30 and the carrier 10. It is not excluded, although certainly not preferred that the chip 30 is assembled to the carrier 10 face-up, and the coupling is provided with bondwires or a separate foil.

FIG. 5 shows the package 100 after provision of the encapsulation 40. That is in this embodiment a sealing layer of parylene. This sealing layer is provided by chemical vapour deposition and afterwards curing at increased temperature. The sealing layer 40 herein does not only extend on the back side 33 of the chip, but also on its front side 34 and around the solder balls 31.

FIG. 6 shows the package 100 after selective removal of the carrier layer 11. Herein the handling means 50 are provided, which are connected to the rest of the package 100 only through the encapsulation 40. The encapsulation now constitutes with the coupling means 20 a substrate for the chip 30. As the coupling means 20 are defined in the top layer only, the handling means 50 effectively form protrusions. When assembled to a foil, the handling means 50 are preferably present on two opposite side faces of the foil. The handling means 50 may then be removed, and the foil can be integrated in or attached to any article, such as a security paper.

1. A flexible package comprising coupling means for electrical coupling to an external component, a chip with contact pads that face the coupling means and are electrically coupled thereto, and an electrically insulating encapsulation encapsulating the chip and being attached to the coupling means, said encapsulation and said coupling means constituting a substrate for the chip, wherein means for handling the package are present that is mechanically connected to the coupling means through the encapsulation only.

2. A package as claimed in claim 1, wherein the encapsulation is a sealing layer.

3. A package as claimed in claim 1, wherein the means for external coupling comprise an antenna for wireless transmission.

4. A package as claimed in claim 1, wherein the means for handling are present on at least two opposite sides of the package.

5. A package as claimed in claim 4, wherein the handling means are defined to be present on adjacent sides of a foil to which the package need to be attached.

6. A package as claimed in claim 1 or 2, wherein the encapsulation extends in apertures between the coupling means such that it is exposed at a side of the coupling means facing away from the chip.

7. A method of manufacturing a flexible package for a chip comprising the steps of:
providing a carrier with a carrier layer and a pattern of electrically conductive tracks defining coupling means;
assembling the chip to the carrier, wherein contact pads of the chip are electrically coupled to the coupling means of the carrier;
providing an encapsulation encapsulating the chip and extending on at least one surface of the carrier, and
removing the carrier layer partially, such that the coupling means can be used for electrically coupling the package to an external component and such that means for handling the package are preserved, which means is mechanically attached to said conductive tracks only through the encapsulation.

8. A method as claimed in claim 7, wherein the encapsulation is a sealing layer.

9. A method as claimed in claim 7, wherein the chip is attached with its contact pads facing the contact pads of the carrier.

10. A method as claimed in claim 8, wherein the sealing layer comprises parylene.

11. A method of assembling a package to a flexible foil, comprising:
providing a package as claimed in any of the claims 1-6, and
attaching the package to the foil.

12. A method as claimed in claim 11, wherein the means for handling the package are removed after the attachment step.

13. An assembly of the package of any of the claim 1-6 and a foil.

14. An assembly of the package and a foil, said package comprising a carrier having means for external coupling, a chip that is attached to the carrier, and contact pads of which chip face the carrier and are electrically coupled to the carrier, and an encapsulation encapsulating the chip and attached to the carrier, said encapsulation extending in apertures in the carrier, said foil being attached to said carrier and said encapsulation extending in the apertures thereof.

15. An article comprising the assembly of any of the claims 14 and 15.

16. An article as claimed in claim 15, wherein the article is a security paper.
